(19) United States
(12) Patent Application Publication
(10) Pub. No.: US 2006/0100107 A1
(43) Pub. Date: May 11, 2006

(54) Superconducting carbon 12 atomic strings and methods of manufacture of cables containing parallel strings

(76) Inventor: Robert W. Beckwith, Clearwater, FL (US)

Correspondence Address: Leo J. Aubel, 111 Rivershire Lane, Lincolnshire, IL, 60069, US

(21) Appl. No.: 10/983,380

(22) Filed: Nov. 8, 2004

(51) Int. Cl. H01L 39/24

(52) U.S. Cl. 505/100

(57) ABSTRACT

A string of carbon 14 atoms forms a superconductor unaffected by temperature changes from absolute zero to the burning point of carbon. A number of carbon 14 atomic strings are connected in parallel and encased in a plastic which forms tubes around each string having a negatively charged inner surface on each tube formed. The superconducting electrons travel in the cylindrical space between the inside of the nanotubes and the outside of the carbon 14 strings. Quarter inch diameter cables carrying 10,000 amperes of electric current and withstanding a million pound pull are projected strings connect to C12 diamond rods at the two ends of a cable both for carrying electric current and for carrying the pulling force.

### BACKGROUND OF THE INVENTION

The electric utility industry is currently using superconductors which require expensive cryogenic cooling.

An overall look at efficiencies of electric power systems in the United States leads to estimates that 10 to 20 percent of prime mover input energy is consumed in electrical losses before it is received by users of electric energy. At 10 cents per kilowatt hour this computes to as much as $50 to $100 billion per year that could possibly be saved by use of loss-less superconductors that require no cryogenic cooling.

Even more savings will result from the use of loss-less superconductors in end use devices. Use of cables of this invention in cities of the future will eliminate the present network of generation, transmission and distribution of electric energy. Use of energy in such cities may be reduced by a factor of 1000.

My purpose of this invention is to explore uses of carbon 12 (C12) in super-dense diamond form. An article in Scientific American magazine in 1984 spoke of C14 diamonds as having hardness' of 10,000 to 20,000 times that of C12 diamonds. At that time I determined that the article had been purged in library copies of the issue and in the magazines file. References to C14 had been removed. My present searches on the internet for super-dense C12 or C14 diamonds found no results. This indicates security classification has been applied to super-dense carbon diamonds.

Also in about 1984 Beckwith Electric Co. hired a technician, Rob Nixon, who had left the Oak Ridge National Lab. which he thought was a dangerous place to work. Among other things he told of the firing of an X-ray laser cannon having a C14 diamond lens strong enough to pass the X-ray beam just before being destroyed by an explosion forming the beam. He was in the field at the time and told of the beam passing overhead with a clap resembling thunder.

C14 is not a practical material for use in superconducting cables however, due to the fact that it is radioactive. Long strings of C14 atoms would have a high probability of failure within a relatively short time due to the radioactive decay of one or more C14 atoms to N14. For this reason I prefer the use of C12 which is not radioactive. Moreover C12 is readily available from coal and many organic compounds.

In this invention I construct principles of super-dense C12 diamonds and diamond strings using basic knowledge of atomic properties.

### PRIOR ART

Prior art is classified and must be deduced from unclassified material. First please consider private conversations between myself and Dr. Henry Bortner of the Central Intelligence Agency (CIA) in approximately the year 1956. As an employee of the General Electric Co., I worked under contract with the CIA and directly with Dr. Bortner. Dr. Bortner told me of hit development of carbon nanotubes in a laboratory owned by the CIA in St. Louis Mo. A strength of several hundred pounds pull for a combination of nanotubes some three feet long was said to be useful to the CIA.

Since 1956 Dr. Bortner has passed away and I have married his widow. Mrs. Evelyn Bortner Beckwith remembers Dr. Bortner mentioning work on nanotubes. I do not know whether Dr. Bortner was aware of superconducting possibilities which the nanotubes that he developed may have had or whether patents were applied for covering Dr. Bortners' work.

Note that the diameter of a carbon atom is approximately 1×10⁻¹⁰ meters. This is one thousand times smaller that something that can be seen using ordinary light Articles describing carbon 12 fibers and showing pictures of results are clearly describing technology unrelated to the present invention.

Carbon 12 nanotubes described as being curved like a roll of chicken wire and closed at both ends by a fullerene type cap are also some 10 times larger than the present inventive C12 atomic strings. Other prior art C12 nanotubes are too small, by a factor of 10, to see with ordinary light, claims of superconductivity of such prior art developments, however, are limited to cryogenic temperatures and unrelated to the present invention which has no temperature limitations under the burning temperature of carbon.

### REFERENCES

1. ENGINEERING PRINCIPLES APPLIED FROM THE ATOM TO THE UNIVERSE WITH TRANSMUTATION OF NITROGEN 14 INTO CARBON 14 AS AN EXAMPLE by Bob Beckwith and Drew Craig. This paper was presented by myself, Bob Beckwith, at a Florida Academy of Science Meeting in Tallahassee Florida Mar. 9, 2001.

The paper was printed and published by the Beckwith Electric Company, 6190-118th Ave. North, Largo Fla. 33773-3724. Tel 727 544 2326 Fax 727 546 0121.

In Reference 1 I extend well known principles of electric motor and generator engineering in introducing far force lines as gravity lines pulling all neutrons and protons of the universe together. I also introduce near force lines which push electrons apart limiting how close atoms can get to each other.

This paper was well accepted by the Florida Academy of Science as the explanation of the High Magnetic Field Laboratory in lifting various things, including live frogs, by magnetic field force lines. These experiments indicate that gravity does not exist other than the pulling force between all neutrons and protons of the universe.
2. UNITED STATES SHIP CARDINAL (MHC 60) COMMISSIONING CEREMONY Oct. 18, 1997 Alexandria. Va.

Reference 2 states:

“The basic hull is a solid, continuous monocoque structure laminated from special fiberglass and resin which flexes to absorb the violent shock of an underwater mine explosion.

Through a unique technology transfer arrangement initiated by the U.S. Navy, this construction was derived from the Italian LERICI class mine countermeasures ship design developed by Intermarine SpA of Le Spezia, Italy, the General Partner of Intermarine USA.”

My wife and I visited the Cardinal in Tampa Fla. on Armed Forces day and were told by our guide that the crew were told not to have anything made of iron on them. They said they were warned that when they teleported a paper clip or staple could be lethal due to the intense magnetic fields being used. They told of being in the Persian Gulf on Friday, ‘blinking’ to Tampa Friday evening and of their plan to be in Japan the next day, Monday.

During the tour we went past a large Marconi cabinet having an LED marked “teleportation mode”. I know of no means, other than C12 atomic strings of the present invention, to carry electric currents from the Marconi cabinet necessary to generate the intense magnetic fields required for teleportation.

The skipper of the Cardinal told us that he didn't try to keep his ships' teleportation travel secret since he had found that none of his visitors on similar tours could accept the truth.
3. THE CRC HANDBOOK OF CHEMISTRY AND PHYSICS, 78th edition

This is referred to hereinunder as required.

### SUMMARY OF THE INVENTION

A super-dense form of a C12 diamond is described as a little known one of the polymorphic forms of carbon. In this form the C12 atoms have collapsed to a state where their valence electron paths coincide. A magnetic field of 8.13 pounds force is required for the nucleus of the atoms to hold the valence atoms in their orbit. When atoms are placed with their field directions alternating in direction a super-dense diamond is formed with a force between atoms of 8.13 pounds in a square lattice of atoms. Extreme temperatures and pressures applied to a conventional C12 diamond are required to form a super-dense C12 diamond. The hardness of the super-dense C12 diamond is some 10,000 times that of a conventional C12 diamond.

A single dimensional super-dense C12 diamond forms a superconducing string with magnetic directions of C12 atoms alternating 180° along the string. Electrons used in forming three dimensional super-dense diamonds are left over in the single dimensional string for carrying superconducting electric currents.

Single superconducting strings of C12 atoms carry approximately one ampere of current and will support 8.13 pounds of pull. It is estimated that ¼″ cables with 10,000 parallel C12 strands could carry 10,000 amperes of electric current and tensional loads of up to 81,300 pounds.

Both single strings and 100×100 stacks of 10,000 parallel strings are smaller than can be seen using ordinary light.

With C12 atoms alternating in the direction of their magnetic field direction, C12 atomic strings use two of the four available valence electrons to form FIG. 8 paths around each two adjacent C12 atoms along a string. In forming the string two loosely bonded electrons are left from each C14 atom with no orbital slot in which to travel. These loosely bonded electrons flow between the exterior of the strings and the inside surface of a special plastic used to form nanotubes around each string in a multi string cable. The special plastic forms negatively charged surfaces along the inside of the nanotubes effectively repelling the superconducting electrons to a cylindrical pathway between the plastic tube and the atomic string. This superconductive capability is not effected by ambient temperatures from just above absolute zero up to the burning point of carbon.

Cables have multiple strings of C12 strings connected in parallel at each of two ends of the cable. At their ends C12 strings are bonded to C12 super-dense C12 diamond rods used both as paths for superconducting currents to enter and leave the C12 strings and also as a pulling attachment for use of the mechanical load capability that the strings give to the cable.

### BRIEF DESCRIPTIONS OF THE DRAWINGS

FIG. 1a A side view of two C12 atoms touching each other with valence electrons bonding them together magnetically.

FIG. 1b An end view corresponding to FIG. 1a.

FIG. 1c A diagram of a C12 diamond.

FIG. 2a A view of 10 C12 atoms forming a superconductive string in a plastic nanotube.

FIG. 2b A cross section of the C12 superconducting string in a plastic nanotube.

FIG. 3a A view of a cross section of a cable having many C12 superconducting strings surrounded by a special plastic forming nanotubes around the strings.

FIG. 3b A view of one end of a superconductive cable showing a C12 diamond terminating rod.

FIG. 4 A view of a container of C12 lamp black in a nitrogen atmosphere along with a device for forming a closely bonded C12 string and pulling from the container.

### DETAILED DESCRIPTION OF THE PREFERRED EMBODIMENT

A super-dense form of a C12 diamond is described as a little known one of the polymorphic forms of carbon. In this form C12 atoms have collapsed to a state where their valence electron paths coincide. A magnetic field of 8.13 pounds force is required for the nucleus of the atoms to hold the valence atoms in their orbit. When atoms are placed with their field directions alternating in direction a super-dense diamond is formed with a bonding force between atoms of 8.13 pounds in a square lattice of atoms. C12 atoms so bonded will be referred to as “closely bonded” hereinbelow.

Extreme temperatures and pressures applied to a conventional C12 diamond are required to form a super-dense C12 diamond. Use of shaped charges to compress conventional C12 diamonds may be required to form super-dense C12 diamonds. The hardness of the super-dense C12 diamond is some 10,000 times that of a conventional C12 diamond.

A single dimensional super-dense C12 diamond forms a superconducing string with magnetic directions of C12 atoms alternating 180° along the closely bonded string. Electrons used in forming three dimensional super-dense diamonds are left over in the single dimensional string useful for carrying superconducting electric currents.

Single superconducting strings of C12 atoms carry approximately one ampere of current and will support 8.13 pounds of pull. It is estimated that ¼″ cables with 10,000 parallel C12 strands could carry 10,000 amperes of electric current and tensional loads of up to 81,300 pounds.

Both single strings and 100×100 stacks of 10,000 parallel strings are smaller than can be seen using ordinary light.

With C12 atoms alternating in the direction of their magnetic field direction, C12 atomic strings use two of the four available valence electrons to form FIG. 8 paths around each two adjacent C12 atoms along a string. In forming the string two loosely bonded electrons are left from each C12 atom with no orbital Blot in which to travel. These loosely bonded electrons flow between the exterior of the strings and the inside surface of a special plastic used to form nanotubes around each string in a multi string cable. The special plastic forms negatively charged surfaces along the inside of the nanotubes effectively repelling the superconducting electrons to a cylindrical pathway between the plastic tube and the atomic string. This superconductive capability is not effected by ambient temperatures from just above absolute zero up to the burning point of carbon.

Cables have multiple strings of C12 strings connected in parallel at each of two ends of the cable. At their ends C12 strings are bonded to C12 super-dense C12 diamond rods used both as paths for superconducting currents to enter and leave the C12 strings and also as a pulling attachment for use of the mechanical load capability that the strings give to the cable.

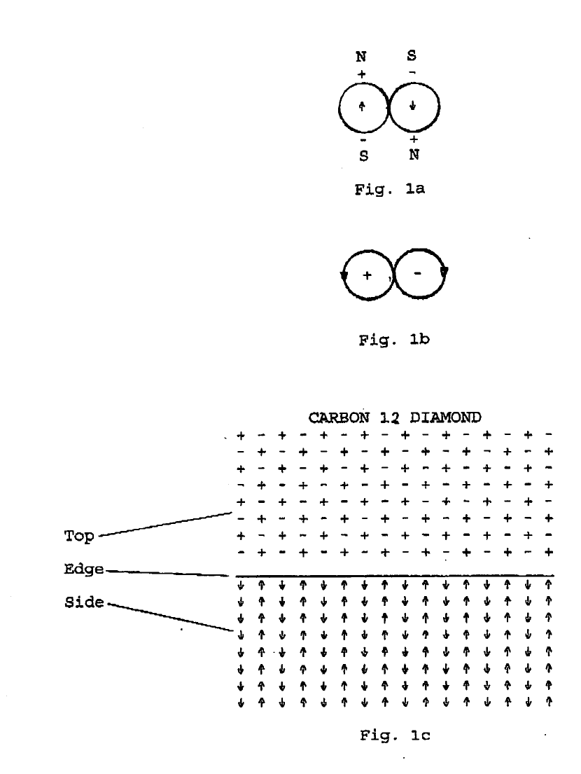

FIG. 1a shows a side view of two closely bonded C12 atoms and FIG. 1b a top view of the same two C12 atoms. The magnetic fields point in different directions with the one to the left having a north (+) pole on top and a south pole (−) on the bottom. The C12 atom to the right is reversed in magnetic polarity from top to bottom as compared with the C12 atom to the left. The two atoms thus attract each other sideways in the first of two possible ways that C12 atoms can be closely bonded.

The magnetic force required by the nucleus of an atom such as C12 to hold its four outer valence atoms in orbit as shown in FIGS. 1a and 1b is derived as follows, referring to Reference 3:
1. The force acting on a moving charge is given by: F_{B}=qv×B where B is the magnetic field vector.

The symbol for B is the Tesla

Tesla is defined as one Newton/(coulomb meter/second)

Since an Ampere is defined as a coulomb/second, therefore
2. 1 Tesla=1 Newton/Ampere meter

For a circulating charge, q, moving at right angles to a uniform magnetic field, the relationship is:
3. r=mv/qB

solving for B, the magnetic field yields:
4. B=mv/qr

For an electron orbiting a nucleus at an average radius of half the atomic diameter, the values would be:
5. B=(9.09×10⁻³¹ kg) (3×10⁸ meter/second)/((1.6×10⁻¹⁹ Coulomb) (0.5×10⁻¹⁰ meters)=3.41×10⁷ Tesla

This is the magnetic field necessary to constrain electrons to their orbit.

The force equal to the magnetic field of equation 5 is found from:
6. F=qv×B

F=(1.6×10⁻¹⁹ Coul.) (3×10⁸ M/s) (3.41×10⁷ T.)

F=1.637×10⁻³ Newtons

since 4.45 Newtons equals approximately one pound;

F=3.68×10⁻⁴ pounds

Note that this is the force that the valence electrons exert on the nucleus.
7. C12 has 12 neutrons and protons in the nucleus thus has a mass of 12.

The difference in mass of a neutron or proton and an electron is approximately 1840.

The magnetic field of the nucleus that attracts electrons and holds them in orbit, is therefore:

F=(3.68×10⁻⁴)×12×1840

F=8.13 pounds

Note that these forces have a direction but, like a rubber band, have no beginning nor end. This then is the force between two atoms located side by side with magnetic fields alternating in direction in a first of two stable orientations of two closely bonded atoms. The same force holds two atoms together with their fields joined head to tail in the second of two stable orientations of two closely bonded atoms.

FIG. 1c illustrates a C12 diamond. When a C12 diamond is formed under extreme temperatures and pressures, the repulsive force between valence electrons of adjacent atoms is exceeded and the atoms collapse together to the point where the outer valence electron orbits coincide. Valence electrons then flow throughout the diamond and no longer exert a repulsive force between the C12 atoms. Magnetic fields generated by magnetic fields of their nucleus hold atoms alternating 180° in direction together giving C12 diamonds their hardness.

The top of the diamond shows a lattice of alternating tops (+) and bottoms (−) of the magnetic fields of C12 atoms. The area shown is 16 atoms across and 8 atoms front to back. Note that two electrons weave FIG. 8 patterns both from front to back and from side to side. Unlike electron paths in single atoms, when in the dense diamond form the electrons follow paths perpendicular to the directions of the magnetic fields shown as in FIG. 1b. These paths overlap with the magnetic fields holding all electrons in planes parallel to the top. The forces make 180° turns at the ends of each row across or front to back.

Down the side, one sees the forces going down from top to bottom and returning in adjacent paths from bottom to top. Each two such paths reverse direction and return at the top and bottom thus completing a “rubber band”.

The edge defines the 90° break between the top and the side of the C12 diamond. Arrows in the first row below the edge show the alternating magnetic fields of the atoms from top to bottom of each horizontal layer of the diamond. Horizontal atomic layers of the diamond are identical to each other. Each layer shows that the magnetic fields of the atoms attract each other end to end in the second of the two ways that C12 atoms stably attract each other.

One can duplicate the structure of closely bonded C12 diamonds using a number of bar shaped permanent magnets. Such magnets will attract each other sideways with polarities reversed and also end to end with polarities reversed. Two planes of such magnets can be made in 4×4 patterns of 16 magnets each. When four such planes are placed one above the other, a very strong cube results.

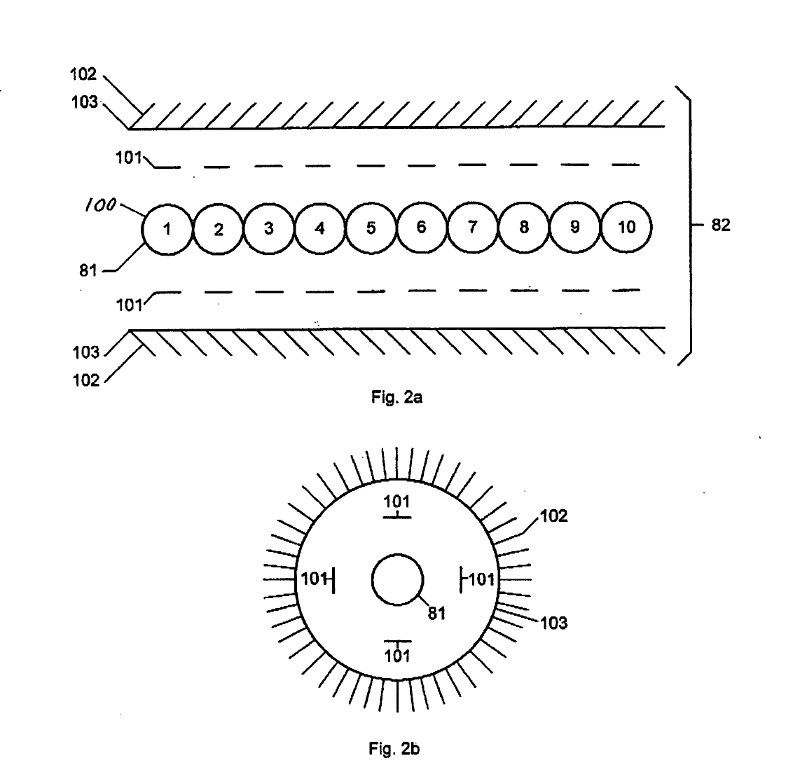

FIG. 2a illustrates a portion of a superconducting string 81 having ten C12 atoms 100 marked 1 through 10. The circles 100 represent the touching orbital paths of the four outer valence electrons of the ten C12 atoms. The diameter of the orbital paths 100 is approximately 1×10⁻¹⁰ meters. Magnetic forces as described under FIGS. 1a and 1b above between touching adjacent C12 atoms 100 equal 8.13 pounds as required to hold the orbital circles 100 together as shown. C12 atomic string 81 has the structure of a single dimensional super-dense C12 diamond.

The touching of the valence circles of the string 81 of C12 atoms permits two valence electrons from an upstream atom and two valence electrons from a downstream atom to orbit each C12 atom. Two electrons travel around each adjacent pair of C12 atoms in a FIG. 8 path as shown by the arrows in FIG. 1b. This forms four electrons orbiting each C12 atom magnetically attracting four orbiting electrons at all times. As shown in FIG. 2a this leaves two electrons 101, for each C12 atom 100, having no orbital position to fill. Electrons 101 are therefore available to carry superconductive currents traveling at the speed of light along the outside of strings 81. Strings 81 are unaffected by ambient temperatures from just above absolute zero to the burning temperature of carbon.

Assuming that the superconducting electrons flow at the speed of light along the outside of the C12 string, one can derive the current flow along a single string 81, again referring to Ref. 3:
1. The diameter of a carbon atom is approximately 1×10⁻¹⁰ meters.
2. The speed of light is 3×10⁸ meters/second.
3. The transit time across each C12 atom is distance/velocity=1×10⁻¹⁰/3×10⁸ meters per second=3.33×10⁻¹⁹ seconds.
4. The number of electrons passing any point along string 81=2/3.33×10⁻¹⁹=6×10¹⁸
5. One Ampere 1 coulomb/second.
6. One Coulomb=6.24×10¹⁸ electrons.
7. The maximum current along a single string 81 is therefore: 6.24×10¹⁸/6×10¹⁸=1.04 Amperes.

As shown in FIG. 2a, a closely bonded spaced string 81 of C12 atoms may be encased in a special plastic 102 so as to form a nanotube 82 with a C12 string 81 in the center. It is the characteristic of the special plastic to form a surface of electrons on the inner surface 103 of the nanotube 82. The two electrons 101 loosely held to each C12 atom 100 and having no position available for orbiting an atom 100 then flow along the nanotube 82 freely at nearly the speed of light. They are held in this cylindrical path between the repulsion of the electrons orbiting atoms 100 and the electrons on the inner surface 103 of nanotube 82.

FIG. 2b shows the cross section of the nanotube 82. Atomic string 81 is shown at the center of nanotube 82. The nanotube 82 is covered with special-plastic 102 having negatively charged inner surface 103. Free electrons 101 are shown traveling lengthwise of the nanotube 82 between negatively charged tube 103 and atomic string 81 negatively charged electron rings 100.

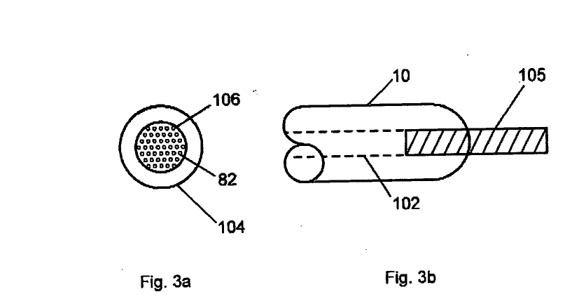

FIG. 3a shows a number of superconducting nanotubes 82 held in parallel along the central portion 106 of a plastic cord 104. The special plastic 102 forms a superconducting nanotube 82 for each said string 81. Super-dense C12 diamond rod terminating member 105 is shown connected to ends of strings 81 within nanotubes 82. The end of the central portion 106 of cord 104 which carries superconducting nanotubes is honed to an optically flat surface. The mating end of C12 diamond 105 is similarly formed with an optically flat surface. The mating the diamond 105 with the end of cord 104 is accomplished by applying ultrasonic vibration to the outer end of diamond 105 sufficient to cause each string 81 to make a strong bond with an atom 100 of C12 on the end of diamond rod 105.

After bonding the terminating diamond rod 105 to cord 104, an outer protective layer 10 of non special plastic is applied. The cord with a C12 diamond rod terminating member is now useable either for loss-less carrying of electric current or for transmitting longitudinal pulling force between ends of the cable.

By vibrating the strings lengthwise via the terminating diamond rods 105 a wide band communication capability can be added.

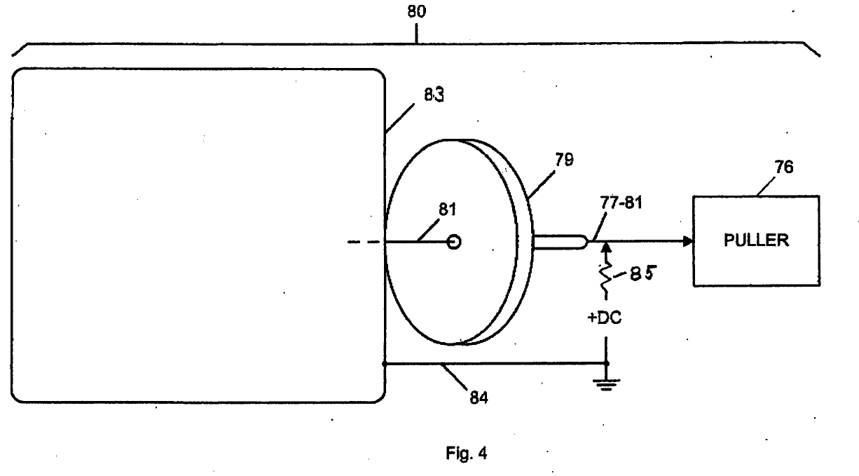

FIG. 4 shows a system 80 for forming closely bonded C12 superconducting strings. Container 83 holds C12 lamp black. This is a dispersion of C12 atomic particles contained in an inert fireproof atmosphere such as nitrogen. Apparatus 80 is shown for forming closely bonded strings 81 of C12 atoms 100 and pulling said strings 81 from the container 83. A small diameter C12 diamond 77 is used for starting the string 81 and for pulling string 81 by puller 76.

A +DC voltage is applied to starter diamond 77 and later to string 81. This causes a tiny spark, limited by resistor 85, to the particles of C12 lamp black thus providing the high temperature required to form a single dimension diamond string 81. Magnet 79 provides the force required to make the close bond between C12 atoms 100 as the string 81 is formed. The pull of puller 76 is adjusted to a constant 4 pounds thus supplying a portion of the force required to form the close bonding between C12 atoms 100 in string 81. The existence of the 4 pound force indicates a string is being formed since the string is otherwise invisible. The +DC voltage is grounded as shown with the ground connected to container 83 by conductor 84.

### ADVANTAGES OF THE INVENTION

1. Superconducting strings for carrying electric currents without the need for cryogenic cooling will eliminate voltage drops and power losses in electric power transmission and distribution lines.

2. Superconducting strings for carrying electric currents without the need for cryogenic cooling will eliminate power losses in electric power generators and transformers.

3. At http://www.metropolismag.com/html/content_{—}0203/fib/Peter Testa Architects describe buildings of the future which use no concrete or steel but rather use plastics and ceramics to suggest buildings that are very strong but also very light as compared to present technology.

It is interesting to assume the success of the present invention and the future use of cords of say 10,000 parallel strands of C12 strings. This could be equivalent to a square bundle of 100×100 strings. These bundles would be 10⁻⁶ meters in size, still too small to see with ordinary light. If 10,000 strings are spread throughout the ¼″ core of a ½″ cable the cable would carry 10,000 amperes of current from building to building. The cables would also have a strength of 8.13 lbs per strand multiplied by 10,000 strands for a pull strength of 81,300 pounds! Such cables could supply bracing for the buildings and support catwalks between buildings at levels above street level. At the same time electric power can be distributed among the buildings over the cables. Some cables might carry 3 Vdc for computers. Other cables might carry 24 Vdc for lighting, air conditioning, etc.

If the C12 string technology is applied to end use devices further changes may be contemplated. The power efficiencies of end use devices can be improved greatly reducing the energy required per person using the buildings.

While the invention has been particularly shown and described with reference to preferred embodiments thereof, it will be understood by those skilled in the art that various changes in form and details may be made therein without departing from the spirit and scope of the invention.

What I claim is:

1. Atomic strings comprising in combination:
a) carbon 12 (C12) atom means for forming strings,
b) force means for pulling said atoms together until their valence electron orbits coincide,
c) down string C12 atoms for forming strings in a first direction,
d) up string C12 atoms for forming strings in a second direction,
e) two valence electron means for orbiting two said C12 atoms in said first direction,
f) two valence electron means for orbiting two said C12 atoms in said second direction,
g) two valence electron means from each said C12 atoms for forming superconductive currents,

2. Atomic strings as in claim 1 further comprising in combination:
a) plastic means for holding multiple said C12 strings connected in parallel,
b) surface means for said plastic for forming negatively charged nanotubes around each said multiple C12 string permitting superconducting electrons to flow in the spaces between said strings and said nanotubes.

3. Atomic strings as in claim 2 further comprising in combination:
a) first said plastic means for forming said nanotubes around said C12 diamond strings,
b) carbon 14 diamond rod means for connecting to ends of said C12 strings contained in said nanotubes,
c) second said plastic means for placing a protective outer cover over said first plastic means thereby forming a cable
whereby both electric currents and lengthwise pull are carried by said C12 diamond rods.

4. Atomic strings as in claim 3 further comprising vibrational communications means for communications via longitudinal vibrations along said cable.
